(19) United States
(12) Patent Application Publication
(10) Pub. No.: US 2012/0018215 A1
(43) Pub. Date: Jan. 26, 2012

(54) HOUSING AND ELECTRONIC DEVICE USING THE SAME

(75) Inventor: YOU-XI WEN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/964,033

(22) Filed: Dec. 9, 2010

(30) Foreign Application Priority Data
Jul. 22, 2010 (CN) 201010233917.8

(51) Int. Cl. H05K 7/20

(52) U.S. Cl. 174/547

(57) ABSTRACT

A housing for an electronic device includes a main body and a ventilated member fixed on the main body. The main body includes a heat dissipating zone. The heat dissipating defines a plurality of heat dissipating holes. The ventilated member defines a heat dissipating chamber communicating with the heat dissipating hole therein and a ventilated hole for introducing airflow into the heat dissipating chamber. The ventilated member forms a covering portion covering the heat dissipating holes.

### BACKGROUND

1. Technical Field

The present disclosure relates generally to device housings, and especially to a housing with heat dissipating holes and an electronic device using the same.

2. Description of Related Art

A commonly used electronic device generally includes a housing defining a plurality of heat dissipating holes on a side surface thereof. However, a size of the heat dissipating holes is often limited to prevent external contact with electronic components housed therein such that heat dissipating ability of the housing is limited accordingly.

Therefore, there is room for improvement within the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is an isometric view of a first embodiment of a housing, the housing including a ventilated member.

FIG. 2 is isometric view of the ventilated member of FIG. 1.

FIG. 3 is an isometric view of a second embodiment of a housing.

### DETAILED DESCRIPTION

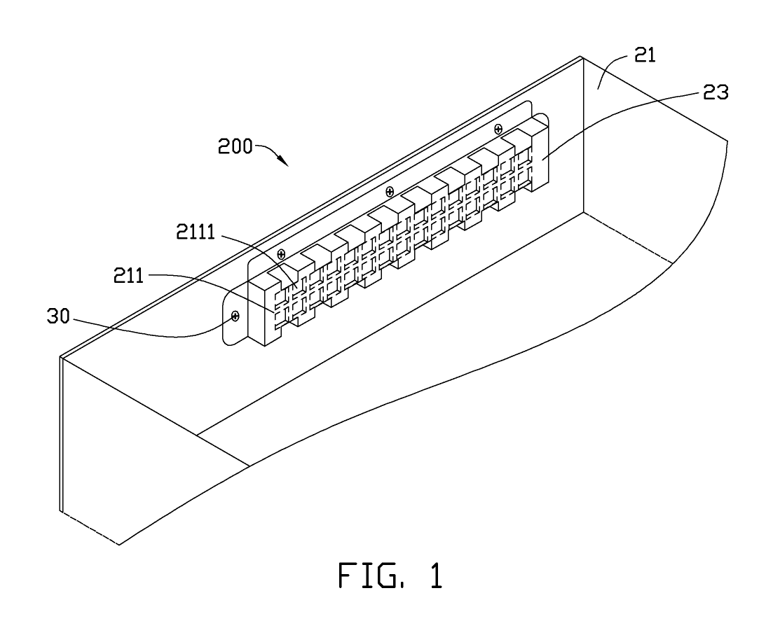

Referring to FIG. 1, a first embodiment of a housing 200 of an electronic device (not shown) includes a main body 21 and a ventilated member 23. The main body 21 forms a rectangular heat dissipating zone 211. The heat dissipating zone 211 defines a plurality of heat dissipating holes 2111. The main body 21 defines a plurality of fixing holes (not shown) for fixing the ventilated member 23. In the illustrated embodiment, the main body 21 is a rectangular computer case. The heat dissipating holes 2111 are rectangular, arranged in two rows. The ventilated member 23 is also rectangular. A width of each heat dissipating hole 2111 is 5 mm (millimeters) or more.

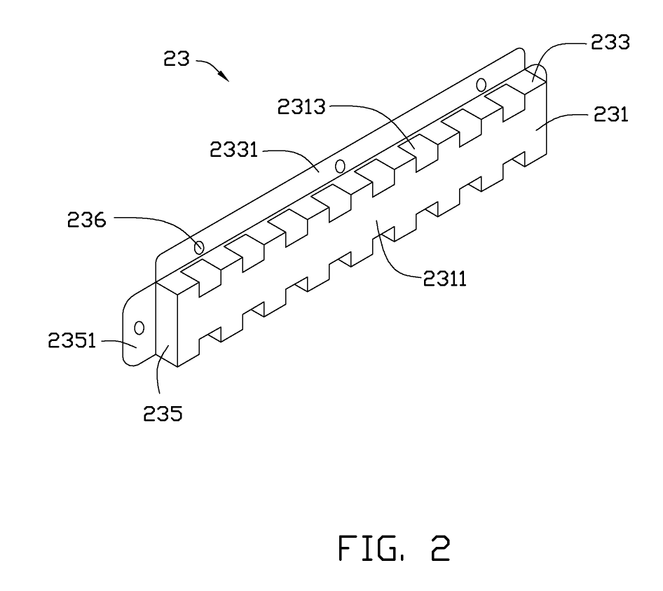

Also referring to FIG. 2, the ventilated member 23 includes a rectangular bottom surface 231, two first sidewalls 233 formed at two opposite edges of the bottom surface 231, and two second sidewalls 235 formed at another two opposite edges of the bottom surface 231. The bottom surface 231, the first sidewalls 233, and the second sidewalls 235 define a rectangular heat dissipating chamber (not shown). Each first sidewall 233 forms a first fixing sheet 2331 extending at an end of the first sidewall 233 away from the bottom surface 231. Each second sidewall 235 forms a second fixing sheet 2351 at an end of the second sidewall 235 away from the bottom surface 231. Both the first fixing sheet 2331 and the second fixing sheet 2351 define through holes 236 therein for fixing the ventilated member 23 on the main body 21. The bottom surface 231 includes a covering portion 2311. The bottom surface 231 defines a plurality of ventilated holes 2313 allowing airflow through the ventilated member 23. In the illustrated embodiment, diversion holes 2313 extend from the bottom surface 231 to the first sidewall 233. Each ventilated hole 2313 is spaced from adjacent ventilated holes 2313. The ventilated holes 2313 are arranged in two rows symmetrically distributed at two sides of the covering portion 2311. Alternatively, the ventilated holes 2313 may be defined on the bottom surface 231, the first sidewalls 233, or the second sidewalls 235.

A plurality of fasteners 30 fix the ventilated member 23 on the main body 21. Each fastener 30 passes through a through hole 236 of the ventilated member 23 and is received in the fixing hole of the main body, to fix the ventilated member 23 on the main body 21. The covering portion 2311 covers heat dissipating holes 2111 of the heat dissipating zone 211, shielding electronic members in the housing 200 in accordance with rule 140 of FIPS (Federal Information Processing Standard). User contact with electronic components in the housing is prevented, further improving security of the electronic device.

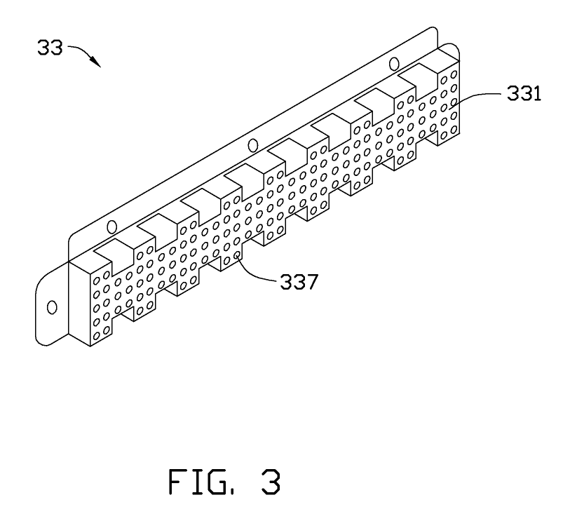

Referring to FIG. 3, a second embodiment of the ventilated member 33 differs from the ventilated member 23 only in the inclusion of a plurality of guiding holes 337 defined on the bottom surface 331. In the illustrated embodiment, the guiding holes 337 are round, with a diameter less than 2 mm. The airflow through the ventilated member 33 may be partly introduced inside by the guiding holes 337, and uniformity of airflow improved.

It is believed that the present embodiments and their advantages will be understood from the foregoing description, and it will be apparent that various changes may be made thereto without departing from the spirit and scope of the disclosure or sacrificing all of its material advantages.

What is claimed is:

1. A housing for an electronic device comprising:
a main body comprising a heat dissipating zone defining a plurality of heat dissipating holes;
a ventilated member fixed on the main body, wherein the ventilated member defines a heat dissipating chamber communicating with the heat dissipating hole therein and a ventilated hole for introducing airflow into the heat dissipating chamber, and the ventilated member forms a covering portion covering the heat dissipating holes.

2. The housing of claim 1, wherein each heat dissipating hole has a width equal to or greater than 5 millimeters.

3. The housing of claim 1, wherein the ventilated member comprises a bottom surface and a first sidewall extending at an edge of the bottom surface, and the ventilated holes extend from the bottom surface to the first sidewall.

4. The housing of claim 1, wherein the ventilated member comprises a rectangular bottom surface, two first sidewalls formed at two opposite edges of the bottom surface, and two second sidewalls formed at another two edges of the bottom surface, the heat dissipating chamber is defined by the bottom surface, two first sidewalls and two second sidewalls, and the ventilated holes extend from the bottom surface to the first sidewall.

5. The housing of claim 1, wherein the heat dissipating holes are arranged in rows, and each heat dissipating hole is spaced from adjacent heat dissipating hole.

6. A housing for an electronic device comprising:
a main body comprising a heat dissipating zone defining a plurality of heat dissipating holes;
a ventilated member fixed on the main body, wherein the ventilated member defines a heat dissipating chamber communicating with the heat dissipating hole therein and a ventilated hole for introducing airflow into the heat dissipating chamber, and the ventilated member forms a covering portion covering the heat dissipating holes, wherein the covering portion defines a plurality of guiding holes.

7. The housing of claim 6, wherein each heat dissipating hole has a width equal to or greater than 5 millimeters.

8. The housing of claim 6, wherein the ventilated member comprises a bottom surface and a first sidewall extending at an edge of the bottom surface, and the ventilated holes extend from the bottom surface to the first sidewall.

9. The housing of claim 6, wherein the ventilated member comprises a rectangular bottom surface, two first sidewalls formed at two opposite edges of the bottom surface, and two second sidewalls formed at another two edges of the bottom surface, the heat dissipating chamber is defined by the bottom surface, two first sidewalls and two second sidewalls, and the ventilated holes extend from the bottom surface to the first sidewall.

10. The housing of claim 6, wherein the heat dissipating holes are arranged in rows, and each heat dissipating hole is spaced from adjacent heat dissipating hole.
